(19) United States
(12) Patent Application Publication
(10) Pub. No.: US 2015/0279658 A1
(43) Pub. Date: Oct. 1, 2015

(54) METHOD OF GROWING NITRIDE SEMICONDUCTOR DEVICE

(71) Applicant: SUMITOMO ELECTRIC INDUSTRIES, LTD., Osaka (JP)

(72) Inventors: Keiichi YUI, Yokohama-shi (JP); Ken Nakata, Yokohama-shi (JP); Isao Makabe, Yokohama-shi (JP); Tsuyoshi KOUCHI, Yokohama-shi (JP)

(73) Assignee: SUMITOMO ELECTRIC INDUSTRIES, LTD., Osaka (JP)

(21) Appl. No.: 14/667,435

(22) Filed: Mar. 24, 2015

(30) Foreign Application Priority Data
Mar. 26, 2014 (JP) 2014-063797

(51) Int. Cl. H01L 21/02; C30B 29/40; C30B 25/16; H01L 29/20; H01L 29/205

(52) U.S. Cl. CPC H01L 21/0262; H01L 29/2003; H01L 29/205; H01L 21/0254; C30B 25/165; C30B 29/403; C30B 29/406

(57) ABSTRACT

A method to produce a nitride semiconductor device is disclosed, The method includes a step to grow sequentially, on a substrate, an AlN layer, a AlGaN layer with the Al composition not less than 2.5% but not greater than 9%, a GaN layer with a thickness not less than 250 nm but not greater than 1400 nm. A feature of the process is that, after the growth of the AlGaN layer but before the growth of the GaN layer, at least the source gases for the group III elements are interrupted to be supplied for a period of not less than 80 seconds but not longer than 220 seconds.

### BACKGROUND OF THE INVENTION

Field of the Invention

The present invention relates to a method to grow a nitride semiconductor device epitaxially.

One type of power semiconductor devices has been attracted, where the power semiconductor devices are often called as the nitride semiconductor device that provides semiconductor materials grouped in gallium nitride (GaN) and has a structure of the high-electron mobility transistor (HEMT). In order to enhance high frequency performance of the GaN-HEMT, an aluminum gallium nitride (AlGaN) layer may he interposed between a semiconductor substrate and the GaN layer, where the semiconductor substrate may be made of silicon carbide (SiC), silicon (Si), and so on, while, the GaN layer operates as a channel layer. The AlGaN layer between the substrate and the GaN layer may induce dislocation in the GaN layer because of the lattice miss-matching between the substrate and the AlGaN layer, and between the AlGaN layer and the GaN layer.

Some prior documents have reported a technique to grow the GaN layer on a primary surface of the Si substrate as interposing aluminum nitride (AlN) between the substrate and the GaN layer, where the primary surface has a specific crystal orientation However, such prior documents have taken the surface of the Si substrate, namely, the lattice miss-matching, dislocations, and so on; but the surface beneath the GaN layer, namely, the interface between the GaN layer and a layer beneath the GaN layer, has been silent. The present application investigates how this interface affects the crystal quality of the GaN layer.

### SUMMERY OF THE INVENTION

An aspect of the present application relates to a method to form a semiconductor device, in particular, the semiconductor device including nitride semiconductor materials. The method comprises steps of: (a) growing an aluminum nitride (AlN) layer on a substrate by an organic metal vapor phase epitaxy (OMVPE), (b) growing an aluminum gallium nitride (AlGaN) layer on the AlN layer by the OMVPE technique as supplying source gases for aluminum (Al), gallium (Ga), and nitrogen (N), where the grown AlGaN layer has an aluminum composition from 3.5 to 9.0%; (c) interrupting the supply of the source gases for the aluminum and the gallium for 80 to 220 seconds; and (d) growing a gallium nitride (GaN) layer on the AlGaN layer by a thickness of 250 to 1400 nm.

### BRIEF DESCRIPTION OF THE DRAWINGS

The foregoing and other purposes, aspects and advantages will be better understood from the following detailed description of a preferred embodiment of the invention with reference to the drawings, in which;

FIG. 1 shows a cross section of a semiconductor device of the first embodiment of the invention;

FIG. 2 shows a cross section of a semiconductor apparatus using the semiconductor device shown in FIG. 1;

FIG. 3 is a time chart showing a behavior of the growth temperature and the supply of the source gases;

FIGS. 4A to 4E show processes to produce the semiconductor device, and FIG. 4F shows a process to form a field effect transistor (FET) using the semiconductor device;

FIG. 5 is a time chart showing a behavior of the growth temperature and the supply of the source gases for a comparable embodiment;

FIGS. 6A and 6B show processes for producing a semiconductor substrate according to the comparable embodiment shown in FIG. 5;

FIG. 7 shows an example of a pit formed in the surface of GaN layer;

FIGS. 8A and 8B show cross sections of the device according to a comparable example of the present invention;

FIG. 9 shows a behavior of the pit density in the surface of the grown GaN layer and the period of interrupting the growth;

FIG. 10A schematically illustrates a cross section of a semiconductor device, where the semiconductor device provides an AlGaN layer with a relatively smaller aluminum composition, and FIG. 10B shows a cross section of another semiconductor device providing an AlGaN layer with a relatively larger aluminum composition;

FIGS. 11A and 11B explain behaviors of the dislocations shown in FIG. 10B;

FIG. 12 schematically illustrates the behavior of the drain current of the transistor with the arrangement shown in FIG. 2;

FIG. 13 shows behaviors of the recovery ratio against the thickness of the GaN layer for various aluminum (Al) compositions in the AlGaN layer;

FIG. 14 shows the relation of the Al composition in the AlGaN layer against the thickness of the GaN layer when the recovery ratio of 70% is obtained;

FIG. 15 overlaps the behavior of the Al composition shown in FIG. 14 with the pit density observed in the surface of the GaN layer against the thickness of the GaN layer;

FIG. 16 shows a relation same as those shown in FIG. 15 but for the device formed by the present invention; and

FIG. 17 schematically illustrates a time chart of the growth temperature and the timings to change the source gases according to one modified process of the present invention.

### DESCRIPTION OF EMBODIMENTS

Next, some embodiments according to the present invention will be described as referring to accompanying drawings. In the description of the drawings, numeral or symbols same with or similar to each other will refer to elements same with or similar to each other without duplicating explanations.

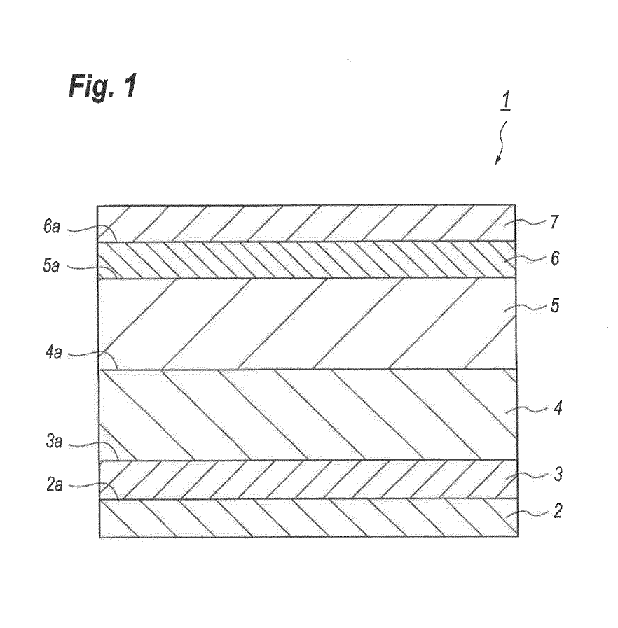

FIG. 1 shows a cross section of a semiconductor device of the first embodiment of the invention. The semiconductor device 1 provides a substrate 2, an AlN layer 3, an AlGaN layer 4, a GaN layer 5, an electron supplying layer 6, and a cap layer 7. The semiconductor layers from the AlN layer 3 to the cap layer 7 are grown on the substrate 2 in this order. The semiconductor device 1 does not always include the electron supplying layer 6 and the cap layer 7.

The substrate 2 is, as described above, provided for the growth of the semiconductor layers. For instance, the substrate 2 may be made of silicon (Si), silicon carbide (SiC), and/or sapphire. The substrate 2 of the present embodiment is a semi-insulating SiC substrate. The surface 2a of the substrate 2 on which the AlN layer 3 is grown is preferably formed in flat, but unnecessary to be a crystallographic flat.

The AlN layer 3, which has a thickness of 30 to 200 nm, plays a role of a buffer layer and a seed layer. That is, the AlN layer 3, even when it is grown on a disordered surface 2a of the substrate 2, provides a flat top surface thereof.

The AlGaN layer 4, which is epitaxially grown on the surface 3a of the AlN layer 3, has a thickness of 300 to 700 nm. The AlGaN layer 4 also plays a function of the buffer layer. The AlGaN layer 4 has a minimum composition of aluminum (Al) atoms of 3.5% and a maximum of 9%. The minimum composition of 3.5% for the Al atoms enlarges the bandgap discontinuity against the GaN layer 5. On the other hand, the maximum composition of 9% for the Al atoms decreases a difference between the lattice constant along the a-axis of the AlGaN layer 4 and that of the GaN layer 5, which enhances the crystal quality of the GaN layer 5.

The GaN layer 5, which is also epitaxially grown on the surface 4a of the AlGaN layer 4, has a minimum thickness around 250 nm and a maximum thickness of 1400 nm. The minimum thickness of 250 nm reduces the number of pits caused in the surface 5a of the GaN layer 5, which enhances an electrical performance including a long-term stability of a semiconductor apparatus using the semiconductor device 1. The maximum thickness of 1400 nm not only reduces the pits but increases the productivity of the semiconductor device 1. The number of the pits caused in the surface 5a of the GaN layer 5 is preferably less than or equal to 10/cm².

The electron supplying layer 6, which is epitaxially grown on the surface 5a of the GaN layer 5, has a thickness of 10 to 30 nm. The electron supplying layer 6 includes a nitride semiconductor material such as AlGaN InAlN, InAlGaN, and so on. The present embodiment provides the electron supplying layer 6 made of AlGaN. The electron supplying layer 6 may be an n-type layer.

The cap layer 7, which is epitaxially grown on the surface 6a of the electron supplying layer 6, has a thickness of 3 to 10 nm. The cap layer 7 may be made of GaN, or made of n-type GaN.

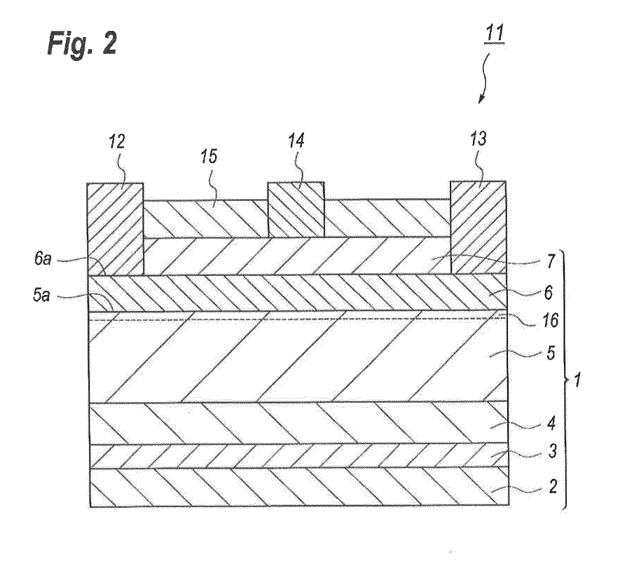

FIG. 2 shows a cross section of a semiconductor apparatus using the semiconductor device 1 shown in FIG. 1. The semiconductor apparatus is a type of the field effect transistor (FET) 11 having a source 12, a drain 13, and a gate 14 on the semiconductor device 1. The FET 11 induces a two dimensional electron gas (2DEG) in the GaN layer 5 at the interface against the electron supplying, layer 6, where the 2DEG becomes a channel 16 of the FET 11. The FET 11 of the present embodiment provides the AlGaN layer 4 underneath the GaN layer 5, and the AlGaN layer 4 has bandgap energy greater than that of the GaN layer 5, which raises the level of the conduction band of the buffer layer including the AlGaN layer 4 and the AlN layer 3 and effectively reduces the short channel effect. Accordingly, the FET 11 may have a shortened gate length and enhance high frequency performance.

The source 12 and the drain 13 are formed directly on the surface 6a of the electron supplying layer 6 by partially removing the cap layer 7. The source and drain, 12 and 13, are ohmic electrodes and have a stack of titanium (Ti) and aluminum (Al), where the Ti is in contact with the electron supplying layer 6. The source and drain, 12 and 13, may have another titanium layer on the Al layer, that is, the aluminum in the stack may be sandwiched by titanium layers.

The gate 14, which is formed on the cap layer 7, is put between the source and drain, 12 and 13. The gate 11 may be a stack of nickel (Ni) and gold (Au). The gate 14 may be formed directly on the electron supplying layer 6 by removing a portion of the cap layer 7 to expose the surface 6a of the electron supplying layer 6.

The insulating layer 15, which is a passivation layer of the FET 11, covers the cap layer 7. The insulating layer 15 may be made of inorganic material such as silicon nitride (SiN).

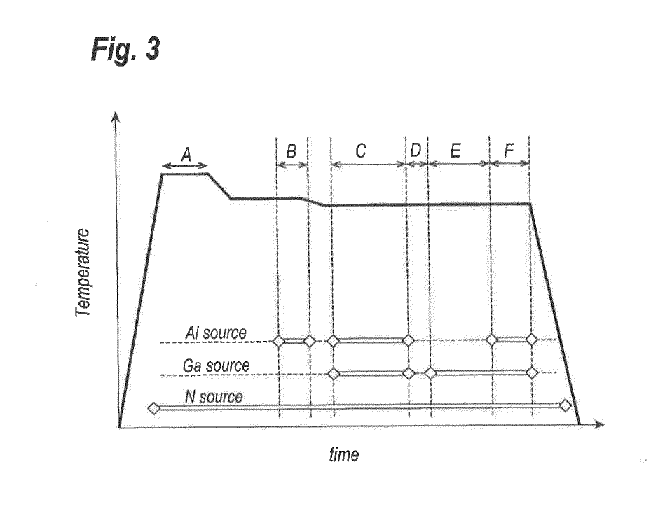

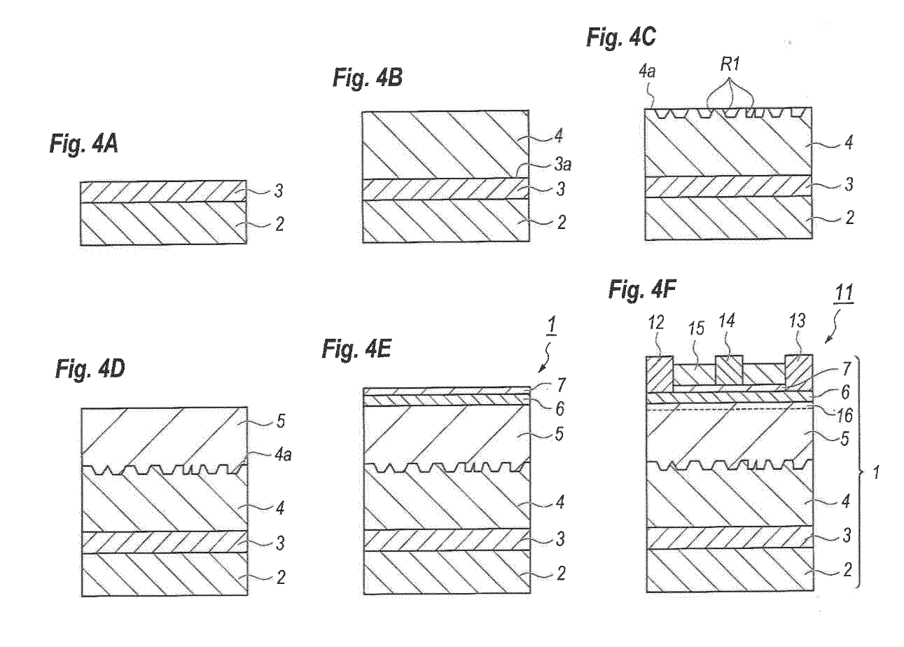

Next, a method to produce the semiconductor device 1 will be explained as referring to FIGS. 3 and 4, where FIG. 3 is a time chart showing a behavior of the growth temperature and the supply of the source gases, FIGS. 4A to 4E show processes to produce the semiconductor device 1, and FIG. 4F shows a process to form the FET using the semiconductor device 1.

The process first sets the substrate 2 in a high temperature as a thermal treatment. For instance, the substrate 2 is set within a growth chamber and raised in a temperature thereof without supplying source gases for the group III material, as shown in FIG. 3. During a period A, the substrate 2 is heat-treated at a temperature of, for instance, 1200° C. as supplying only for the group V material. The present embodiment supplies ammonia (NH₃) as the source gas for nitrogen. However, the process may leave the substrate 2 without supplying any source gases.

Next, as shown in FIG. 3 and FIG. 4A, the process grows the AlN layer 3 on the SiC substrate 2 during a period B. Specifically, the AlN layer 3 is grown under conditions of a temperature of 1100° C. which is lowered by about 100° C. from the temperature of the thermal treatment of the substrate 2 and a pressure of 13.3 kPa as supplying tri-methyl-aluminum (TMA) as a source gas for aluminum and ammonia as a source gas for nitride.

Then, as shown in FIG. 48, the AlGaN layer 4 is grown on the AlN layer 3 in a period C under conditions of a temperature of 1080° C., which is slightly lowered from the former condition, and a pressure of 13.3 kPa as supplying tri-methyl-gallium (Ga) as a source gas for gallium, the TMA, and the ammonia. The supply of the TMA is interrupted after the growth of the AlN layer 3 and resumed in the period C. On the other hand, the ammonia is continuously supplied between two periods, B and C. The flow rates of the source gases are 100 μmol/min, 120 μmol/min, and 0.5 mol/min for TMA, TMG, and ammonia, respectively. Under such growth conditions of the temperature, the pressure, and the flow rates the AlGaN layer 4 is grown to a thickness of 500 nm by a growth rate of 0.4 nm/sec.

Subsequently, the process interrupts the growth of semiconductor materials in a period D between the periods C and E. Specifically, the process cuts the supply of the source gases for the group III materials. That is, the TMA for aluminum and the TMG for gallium are cut to be supplied within the growth chamber but the ammonia, which is the source gas for the nitrogen, continues the supply by the flow rate same with that in the former period C. That is, the ammonia is continuously supplied by the flow rate of 0.5 mol/min during the periods C and D. The period D is preferably longer than or equal to 80 seconds but shorter than or equal to 220 seconds. The present embodiment sets the period D in 180 seconds. During the period D, the surface of the AlGaN layer 4 causes many dimples R1 as shown in FIG. 4C. The sublimation of GaN in the AlGaN layer 4 during the period D is considered to be a reason for inducing the dimples R1. The temperature during the period D is optional, which may be equal to the temperature in the period C, or different from the temperature of the period C. The temperature in e period D is preferably between 1050 to 1150° C.

The process next grows the GaN layer 5 on the AlGaN layer 4 in the period E, as shown in FIG. 4D. Supplying source gases for gallium (Ga) and nitrogen (N) under a temperature of, for instance, 1080° C., and a pressure of 13.3 kPa, the GaN layer 5 is grown on the AlGaN layer 4 by a growth rate of 0.4 nm/sec to a thickness of 500 nm. The flow rate of the source gas for nitrogen (N) la set to be 0.5 mol/min, and that for gallium, (Ga) is set to be 120 μmol/min.

Next, the AlGaN layer is grown on the GaN layer 5 during the period F for the electron supplying layer 6. Supplying source gases for aluminum (Al), gallium (Ga), and nitrogen (N) under a pressure of 13.3 kPa and a temperature of 1080° C., the electron supplying layer 6 is grown on the GaN layer 5 by the OMVPE method with a thickness of 20 nm. The process may continuously grow another GaN layer as the cap layer 7 as cutting the source gas for aluminum (Al) but continuously supplying source gases for gallium (Ga) and nitrogen (N), as shown in FIG. 4E. The growth of the cap layer 7 is done by conditions of the growth temperature of 1080° C. and the pressure of 13.3 kPa. The grown GaN layer has a thickness of, for instance, 5 nm. Thus, the semiconductor device 1 has been completed.

Also, as shown in FIG. 4F, a FET 11 may be formed on the semiconductor device 1. Removing a portion of the cap layer 7 using photolithography, a source 12 and a drain 13 are formed on the AlGaN layer 6 exposed by the removal of the cap layer 7. Similarly, a gate 14 is formed on the cap layer 7. Finally, a passivation layer 15 covers a whole surface of the transistor. The stack of the AlGaN layer on the GaN layer 5 induces the two-dimensional electron gas (2DEG) in the interface 5a therebetween, and this 2DEG operates as the channel 16 of the FET 11.

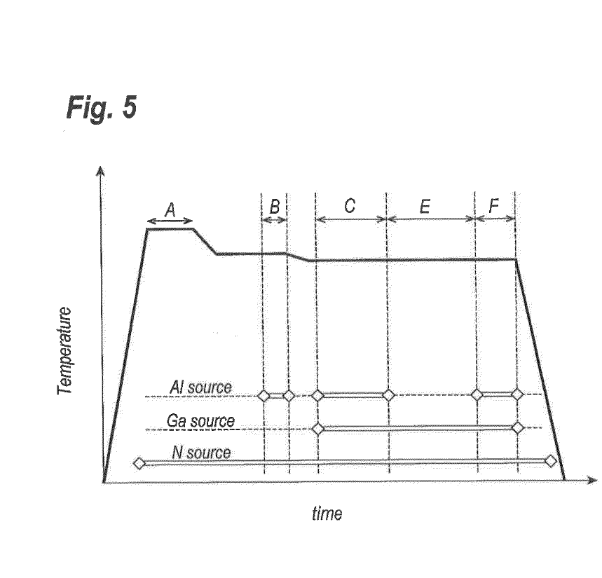

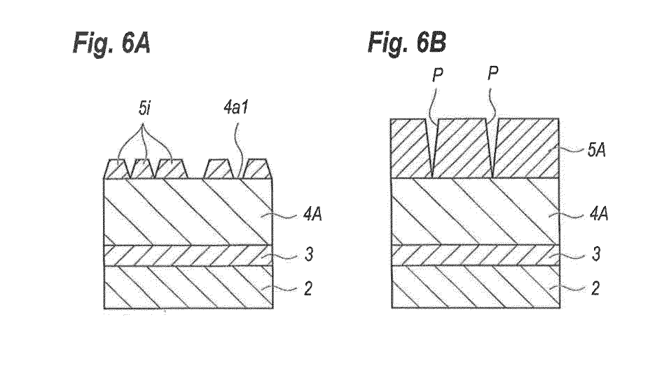

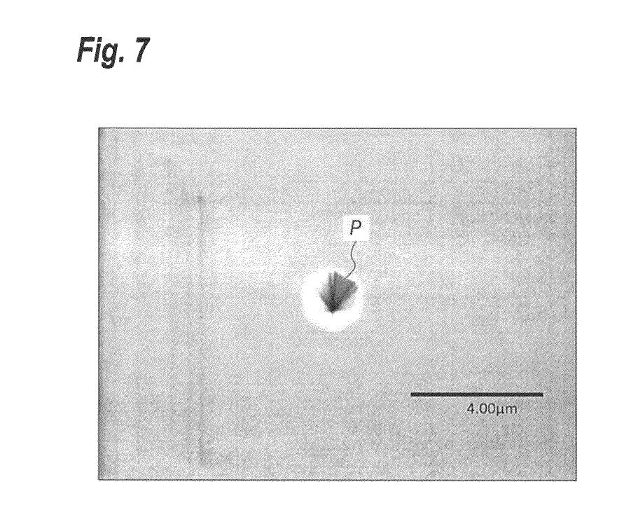

FIG. 5 is a time chart showing a behavior of the growth temperature and the supply of the source gases for a comparable embodiment. FIGS. 6A and 6B show processes for producing a semiconductor substrate according to the comparable embodiment shown in FIG. 5, and FIG. 7 shows an example of a pit formed in the surface of GaN layer.

As shown in FIG. 5, the process according to the comparable example omits the period D between the periods C and E. That is, the process shown in FIG. 5 has no period to interrupt the growth of semiconductor layers. In such a case, when the GaN layer 5A is grown on the surface 4a1 of the AlGaN layer 4A, the vertical growth of the GaN layer 4 along the direction of the thickness of the layer is enhanced to form a plurality of GaN islands 5i isolated to each other. No GaN is filled between the islands 5i. Further processing the growth of the GaN layer 4, the GaN layer 5A causes many pits P between the islands 5i, where the pits P show a hexagonal plane shape. Ordinarily, a thick GaN layer, for instance, thicker than 1400 nm, is grown to reduce the number of the pits P.

The method of the present invention, as shown in FIG. 3, provides the period D, during which dimples R1 are formed on the surface 4a of the AlGaN layer 4. The dimples R1 may enhance the lateral growth of the GaN layer 5 in the beginning of the period E, which fills gaps between nuclei of the GaN crystal at the beginning of the growth, the GaN layer 5 with a planar surface may be grown. Even the GaN layer 5 is relatively thin, for instance, 250 to 1400 nm, the GaN layer 5 in the surface 5a thereof may decrease the number of the pits.

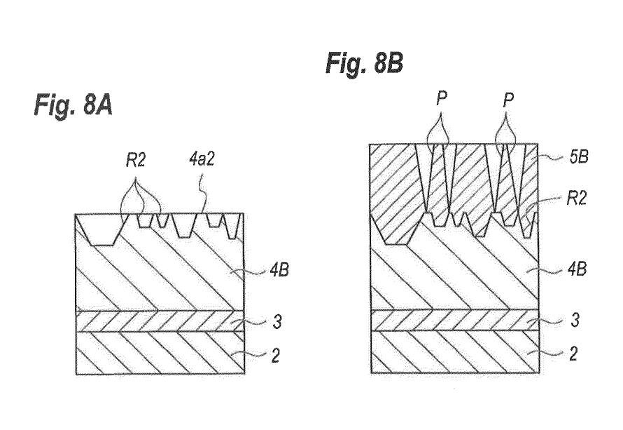

FIGS. 8A and 8B show cross sections of the device according to a comparable example of the present invention. The present invention provides the period D between the completion of the grown of the AlGaN layer 4 and the beginning of the grown of the GaN layer 5 as described above. When the period D is too long, the AlGaN layer 4 in the surface 4a2 thereof causes roughness R2 whose size is greater than that of the dimples R1 illustrated in FIG. 4C. For such a surface 4a2 of the AlGaN layer 4, even when the lateral growth of the GaN layer 5B may be enhanced at the beginning of the growth thereof, the roughness is sometimes left unfilled by the GaN layer 5B, as shown in FIG. 8B. A GaN layer with a planar surface is never obtained. Only the GaN layer 5B whose surface accompanies with many pits P is obtained.

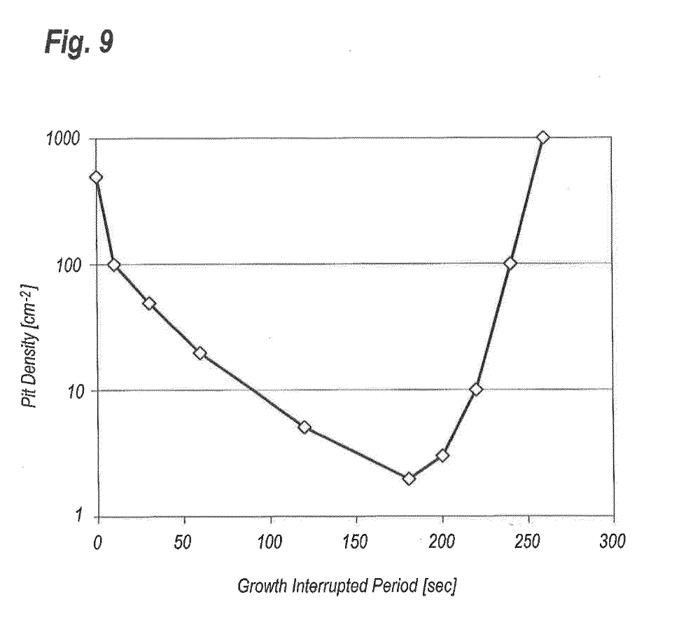

FIG. 9 shows a behavior of the pit density in the surface of the grown GaN layer and the period of interrupting the growth. For the interrupted periods until 180 seconds, the pit density induced in the surface of the GaN layer 5 monotonically decreases. Especially, for the interrupted period longer than 80 seconds, the pit density becomes less than 10 cm⁻². However, when the interrupted period exceeds 180 seconds, the pit density increases; especially, the pit density rapidly increases when the interrupted period becomes longer than 220 seconds, at which the pit density becomes 10 cm⁻². This is due to the phenomenon that too long interrupted period of the growth enhances the roughness of the surface of the grown AlGaN layer 4 to obstruct a homogeneous growth of the GaN layer 5. Accordingly, the interrupted period D of the growth is preferably longer than or equal to 80 seconds but shorter than or equal to 220 seconds.

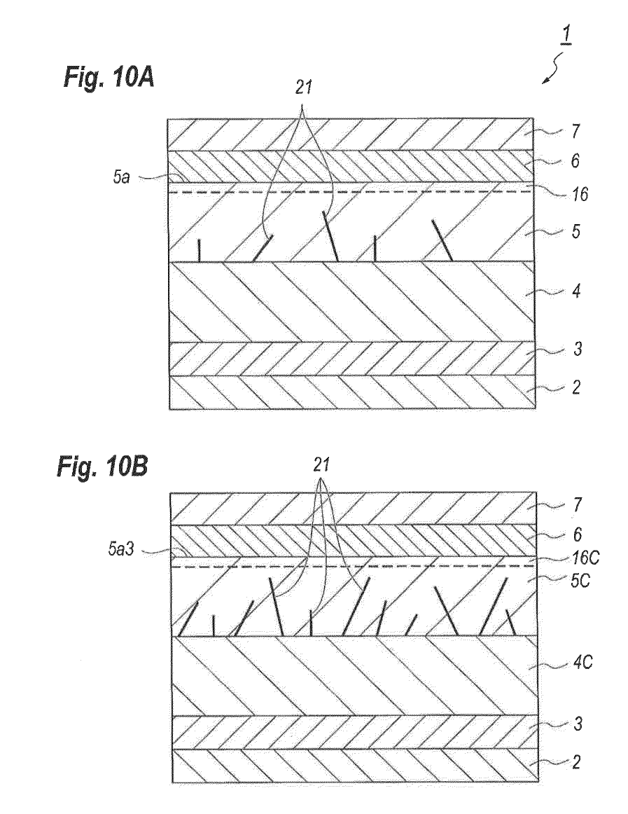

FIG. 10A schematically illustrates a cross section of a semiconductor device 1 same with that shown in FIG. 1, where the semiconductor device 1 provides an AlGaN layer with a relatively smaller aluminum composition, and FIG. 10B shows a cross section of another semiconductor device providing an AlGaN layer with a relatively larger aluminum composition. The GaN layer 5 of FIG. 10A causes dislocations 21 induced from the surface of the AlGaN layer 4 to the GaN layer 5. Similarly, the device of FIG. 10B induces dislocations 21 from the surface of the AlGaN layer 40 to the GaN layer 5C. These dislocations are due to the mismatch of the lattice constant along the axis a between the AlGaN layer, 4 or 4C, and the GaN layer, 5 or 5C. The mismatch of the lattice constant expands as the aluminum composition in the AlGAN layer 4 or to becomes large. Accordingly, the aluminum composition of the AlGaN layer 4 is preferably greater than or equal to 3.5% and smaller than or equal to 9%. The aluminum composition of the AlGaN layer 4 may be measured by the X-ray diffraction.

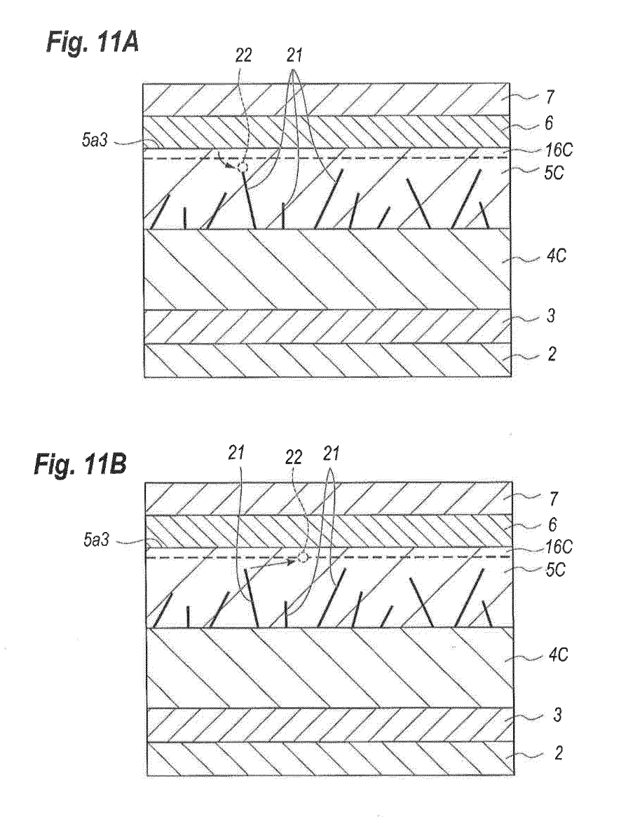

FIGS. 11A and 11B explain behaviors of the dislocations shown in FIG. 10B. As shown in FIG. 11A when the electrons flow in the channel 16C formed in the GaN layer 5C in a portion close to the interface to the electron supplying layer 6, some of electrons 22 are captured by the dislocations 21. That is, the dislocations behave as the electron traps. Also, as shown in FIG. 11B, the electrons 22 once captured by the electron traps are released with a time lag. The released electrons 22 move to the channel 16C. Such a mechanism of the capture and release of the electrons 22 by the dislocations 21 in the GaN layer 5C is reflected in the transient response of the current. Forming a transistor on a semiconductor substrate that shows the transient response, the current of the transistor, for instance, the drain current shows the transient response, or, shows the instability in long duration. The instability of the current, usually the decrease of the current, depends on the density of the dislocation in the layer on the substrate. Accordingly, the semiconductor device 1 shown in FIG. 10A with a lesser dislocation 21 may suppress the instability or the decrease of the current compared with the substrate shown in FIG. 10B which has more dislocations 21. The semiconductor device 1 of the present invention may effectively suppress the dislocations induced in the GaN layer 5 mainly due to the roughness of the interface between the AlN layer 4 and the GaN layer 5, as shown in FIG. 4F, and the current instability/decrease may be effectively suppressed.

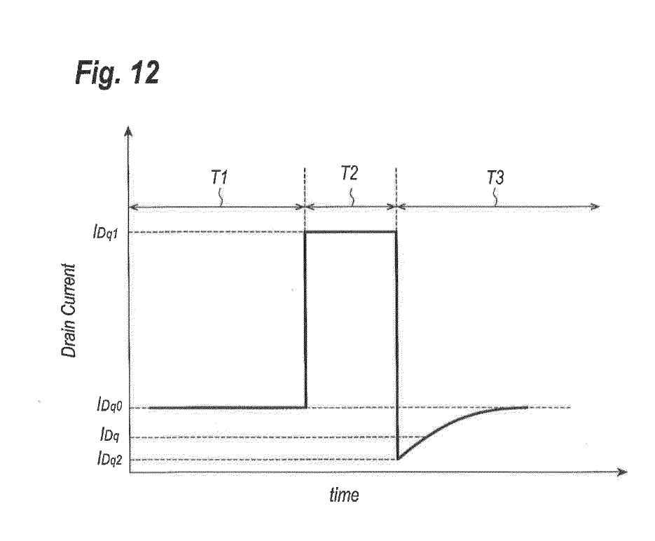

FIG. 12 schematically illustrates the behavior of the drain current of the FET 11 with the arrangement shown in FIG. 2, where the horizontal axis corresponds to time, while the vertical axis shows the drain current. The FET 11 stands by for a period T1 as receiving a gate bias to flow a relatively small drain current Idq0. For the next period T2, the transistor receives a large gate bias to cause a large drain current of Idq1. Finally, the gate bias of the FET 11 recovers the initial one for the period T3, but the drain current over decreases once to Idq2, which is far less than the initial magnitude Idq0, then gradually recovers the initial magnitude of Idq0. This behavior of the drain current is just due to the transient response described above. Specifically, at the switching from the period T2 to the next period T3, some electrons flowing in the GaN layer 5 as the drain current are captured by the dislocations 21. Accordingly, the over-decrease of the drain current to the magnitude Idq2 occurs. The electrons 22 captured by the dislocations 21 are released. therefrom with a time duration and the drain current gradually recovers to the initial magnitude Idq0 by recovering the released electrons in the channel 16. Setting a ratio of the drain current Idq measured one second after the beginning of the period T3 against the initial magnitude Idq0, that is, Idq/Idq0 is the recovery ratio; a practical transistor preferably has this recovery ratio greater than 70%.

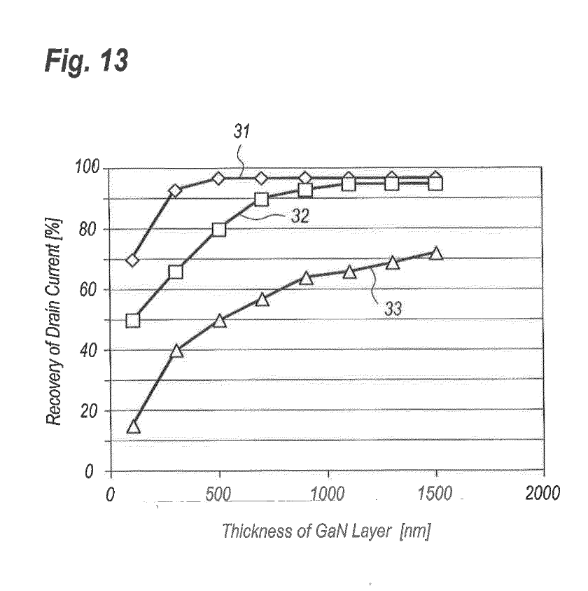

FIG. 13 shows behaviors of the recovery ratio against the thickness of the GaN layer for various aluminum (Al) compositions in the AlGaN layer. The vertical axis shows the recovery ratio, while, the horizontal axis corresponds to the thickness of the GaN layer. For the AlGaN layer with the Al composition of 2%, which is denoted by the behavior 31, shows the recovery ratio of 70% at the thickness of the GaN layer of 100 nm and the recovery ratio gradually increases to 100% as the GaN layer becomes thicker. For the AlGaN layer with the Al composition of 5%, the recovery ratio of 70% may be obtained for the thickness of the GaN layer of 400 nm. The AlGaN layer with the Al composition of 9% denoted by the behavior 33 shows the recovery ratio of 70% at the thickness of the GaN layer of 1300 nm.

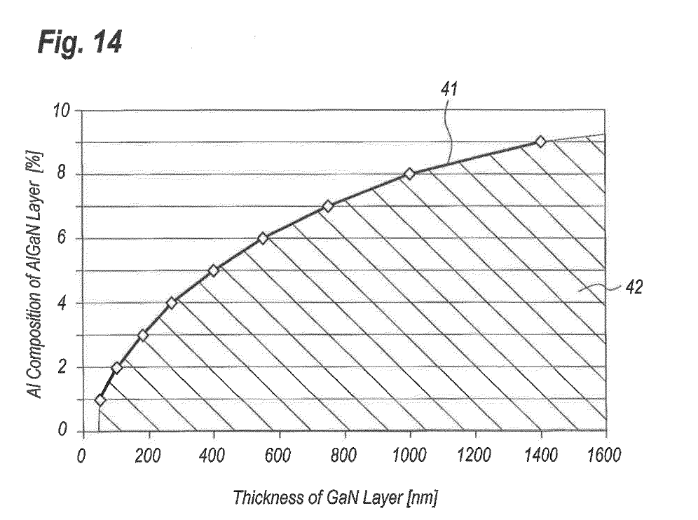

FIG. 14 shows the relation of the Al composition in the AlGaN layer against the thickness of the GaN layer when the recovery ratio of 70% is obtained. As shown in FIG. 14, the Al composition by which the recovery ratio becomes 70% monotonically increases as the thickness of the GaN layer increases. The hatched area 42 demarcated by the behavior 41 of the Al composition corresponds to a region where the recovery ratio exceeds 70%.

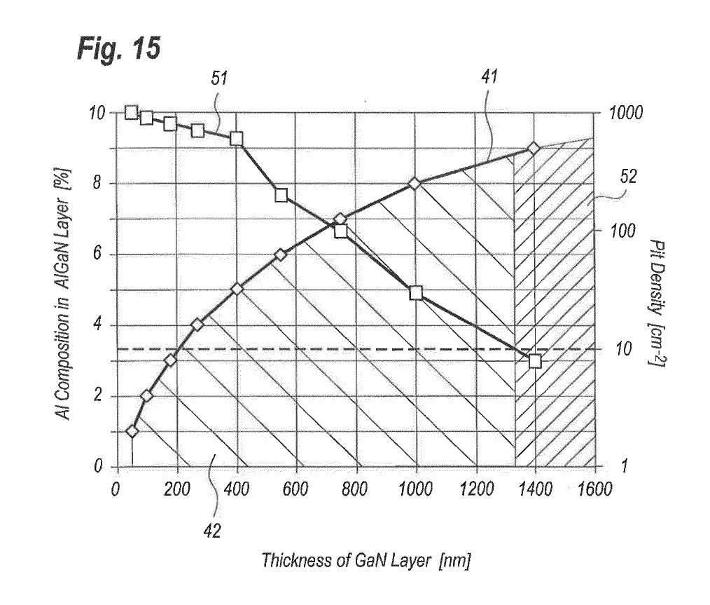

FIG. 15 overlaps the behavior of the Al composition shown in FIG. 14 with the pit density 51 observed in the surface of the GaN layer against the thickness of the GaN layer. When the thickness of the GaN layer exceeds 1300 nm the pit. density becomes less than or equal to 10/cm² for the substrate formed by the comparable method. Further specifically, the device formed by the comparable example shows the pit density less than or equal to 10/cm² and the recovery ratio greater than 70% in a hatched region 52, namely, the thickness of the GaN layer is thicker than 1300 nm and the Al composition less than 8.8%.

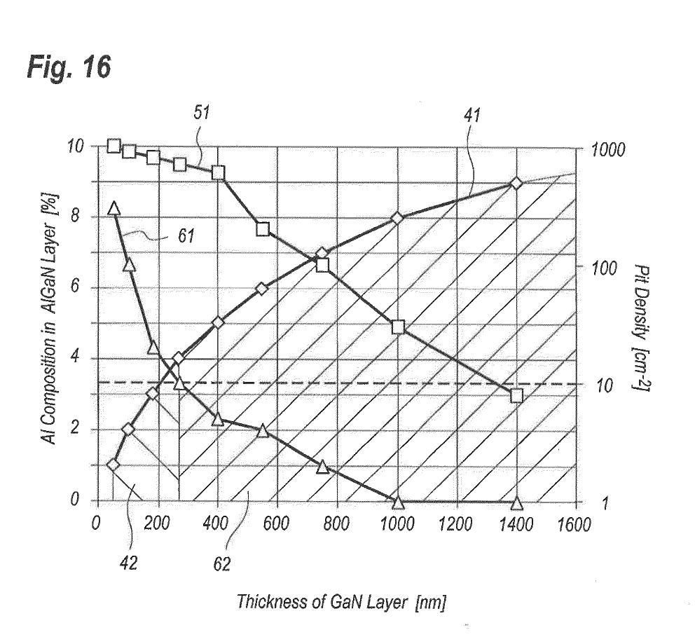

FIG. 16 shows a relation same as those shown in FIG. 15 but for the device formed by the present invention. That is, the surface pit density 61 is added to FIG. 16. As shown in the behavior 61, the thickness of the GaN layer greater than 250 nm gives the surface pit density less than or equal to 10/cm². For the device formed by the method of the present invention, the conditions the surface pit density less than or equal to 10/cm² and the recovery ratio greater than 70% are given by the hatched area 62 in FIG. 16, which is expanded from the hatched area of FIG. 15, and corresponds to the thickness of the GaN layer greater than 250 nm.

The process for manufacturing the semiconductor device according to the present invention interrupts the supply of the source gases for the group III elements after the growth of the AlGaN layer 4 but before the growth of the GaN layer 5 for at least 80 seconds but less than 220 seconds. The interruption of the source gases forms microscopic. dimples R1 on the surface of the AlGaN layer 4. Those dimples R1 enhances the lateral growth of the GaN layer 5 to form a plane GaN layer 5 on the surface 4a of the AlGaN layer 4, which enhances the crystal quality of the GaN layer 5 and may upgrade the electrical performance of the device formed on the AlGaN layer 4 and the GaN layer 5.

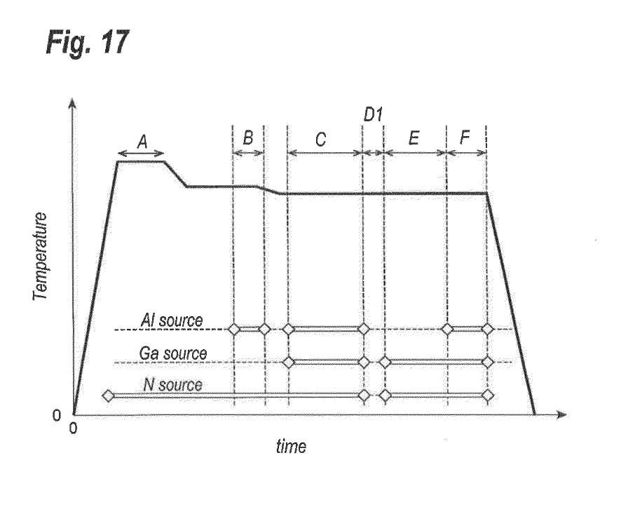

FIG. 17 schematically illustrates a time chart of the growth temperature and the timings to change the source gases according to one modified process of the present invention. A feature of this modified process is that, during the interruption D1 of the source gases for the group III materials, the source gas for the group V material, that is, ammonia for nitride (N), is also interrupted to be supplied into the growth chamber. Even when all source gases including those for the group III elements is interrupted to be supplied, micro dimples R1 are formed on the surface 4a of the AlGaN layer 4 and the lateral growth of the GaN layer 5 may be enhanced. Moreover, interrupting the source gas for the group V elements, the process cost, in particular, the volume of ammonia may be drastically saved. As already described, the supply rate of the source gas for the group V element is tremendous compared with the consumption of the source gases for the group III elements.

While particular embodiments of the present invention have been described, herein for purposes of illustration, many modifications and changes will become apparent to those skilled in the art. For instance, conditions to grow the AlN layer, the AlGaN layer, and the GaN layer on the substrate may be optionally changed depending on the growing apparatus and so on. Accordingly, the appended claims are intended to encompass all such modifications and changes as fall within the true spirit and scope of this invention.

What is claimed is:

1. A method to form a semiconductor device comprising steps of:
(a) growing an aluminum nitride (AlN) layer on a substrate by an organic metal vapor phase epitaxy (OMVPE);
(b) growing an aluminum gallium nitride (AlGaN) layer on the AlN layer by the OMVPE as supplying source gases for aluminum (Al), gallium (Ga), and nitrogen (N), where the AlGaN layer has an aluminum composition from 3.5 to 9.0%;
(c) interrupting supply of the source gases for the aluminum and the gallium for 80 to 220 seconds; and
(d) growing a gallium nitride (GaN) layer on the AlGaN layer by a thickness of 250 to 1400 nm.

2. The method of claim 1,
wherein the step (c) includes a step of interrupting the source gas for nitrogen.

3. The method of claim 1,
wherein the step (b) includes a step of supplying a tri-methyl-gallium (TMG) and a tri-methyl-aluminum (TMA) as the source gases for the group III materials and an ammonia (NH₃) as the source gas for the group V material.

4. The method of claim 1,
wherein the steps from (a) to (d) include a step of supplying the source gas for nitrogen continuously.

5. The method. of claim 1,
wherein the steps from (b) to (d) include a step of keeping a temperature in constant.

6. The method of claim 5,
wherein the temperature kept in constant in the steps (b) to (d) is lower than a temperature under which the AlN layer is grown at the step (a).

7. The method of claim 1,
wherein the step (c) includes a step of setting a temperature same with a temperature in the step (b).

8. The method of claim 7,
wherein the step (c) includes a step of setting a temperature different from a temperature in the step (b).

9. The method of claim 1,
further including before the step (a), a step of treating the substrate in a temperature higher than a temperature in the step (a).

10. The method of claim 1,
wherein the steps (a), (b), and (d) are carried out under a pressure same to each other.

11. The method of claim 1,
wherein the step (c) interrupts the supply of the source gases for the aluminum and the gallium for 100 to 200 seconds.

12. A semiconductor device, comprising:
a substrate;
an aluminum nitride (AlN) layer provided on the substrate;
an aluminum gallium nitride (AlGaN) layer provided on the AlN layer, the AlGaN layer having an aluminum composition of 2.5 to 9.0%; and
a gallium nitride (GaN) layer provided on the AlGaN layer, the GaN layer having a thickness of 250 to 1400 nm.

13. The semiconductor device of claim 12,
wherein the GaN layer has pit density less than or equal to 10/cm² in a top surface thereof.
